(19) United States
(12) Patent Application Publication
(10) Pub. No.: US 2026/0189188 A1
(43) Pub. Date: Jul. 2, 2026

(54) AUDIO AMPLIFICATION DEVICE

(71) Applicant: ELITE SEMICONDUCTOR MICROELECTRONICS TECHNOLOGY INC., Hsinchu City (TW)

(72) Inventors: ZIH-SIANG SYONG, Hsinchu City (TW); ISAAC Y. CHEN, Hsinchu City (TW)

(73) Assignee: ELITE SEMICONDUCTOR MICROELECTRONICS TECHNOLOGY INC., Hsinchu City (TW)

(21) Appl. No.: 19/006,257

(22) Filed: Dec. 31, 2024

(51) Int. Cl. H03F 1/02; H03F 1/30; H03F 3/185; H03G 3/30

(52) U.S. Cl. CPC H03F 1/0227; H03F 1/305; H03F 3/185; H03G 3/3026; H03F 2200/03

(57) ABSTRACT

An audio amplification device includes a charge pump circuit and an operational amplifier. The charge pump circuit generates an output voltage when receiving a power-on reset signal. The operational amplifier has a first input terminal for receiving a first input signal, a second input terminal for receiving a second input signal, a third input terminal for receiving the output voltage, a fourth input terminal for receiving a switching signal output, and an output terminal. The operational amplifier generates an amplified signal at the output terminal according to the first and second input signals, the output voltage and the switching signal output and outputs the amplified signal to a load circuit. When a level of the power-on reset signal changes from a high logic level to a low logic level, the operational amplifier is controlled by the switching signal output to pull a potential of the output terminal to zero.

### BACKGROUND OF THE INVENTION

### 1. Field of the Invention

The present disclosure relates to an amplification device, and in particular relates to an audio amplification device.

### 2. Description of the Related Art

Referring to FIG. 1, a conventional audio amplification device 1 is an electronic device for amplifying a low-power audio signal, and includes an operational amplifier 11, a capacitor 12, a resistor 13, and a resistor 14. The operational amplifier 11 receives an audio signal VIN from its inverting input terminal, and amplifies the audio signal VIN, and outputs an amplified signal AM from its output terminal to a load circuit 15. In terms of application, the load circuit 15 may be a loudspeaker, such as a headset or a speaker. The operational amplifier 11, the capacitor 12, the resistors 13, and the resistor 14 are implemented on a chip.

However, when the audio amplification device 1 shuts down, output impedance of the audio amplification device 1 is connected in parallel with the load of the load circuit 15, and the higher the parallel impedance is, the more serious the shutdown attenuation of the audio amplification device 1 is. Therefore, how to reduce the output impedance of the audio amplification device 1 when shutting down to reduce the parallel impedance to improve a problem of shutdown attenuation is a main focus of the present disclosure.

### BRIEF SUMMARY OF THE INVENTION

Therefore, an object of the present disclosure is to provide an audio amplification device that can reduce output impedance when the audio amplification device shuts down to improve the problem of shutdown attenuation, so as to overcome the shortcomings of the prior art.

Hence, the audio amplification device of the present disclosure includes: a charge pump circuit, configured to generate an output voltage when receiving a power-on reset signal; and an operational amplifier, having a first input terminal for receiving a first input signal, a second input terminal for receiving an audio signal, a third input terminal coupled to the charge pump circuit to receive the output voltage, a fourth input terminal for receiving a switching signal output, and an output terminal, where the operational amplifier generates an amplified signal at the output terminal according to the first input signal, the audio signal, the output voltage, and the switching signal output, and outputs the amplified signal to a load circuit; and when a level of the power-on reset signal changes from a high logic level to a low logic level, the operational amplifier is controlled by the switching signal output to pull down a potential of the output terminal to zero potential.

In some embodiments, the operational amplifier of the audio amplification device of the present disclosure includes: a gain adjustment circuit, coupled to the first input terminal to the third input terminal of the operational amplifier to receive the first input signal, the audio signal, and the output voltage, respectively, and performing gain adjustment according to the first input signal, the audio signal, and the output voltage to generate a first output signal and a second output signal; and an output circuit, configured to receive the switching signal output, and coupled to the gain adjustment circuit to receive the first output signal and the second output signal, and coupled to the charge pump circuit to receive the output voltage, where the output circuit generates the amplified signal at the output terminal of the operational amplifier according to the switching signal output, the first output signal, the second output signal, and the output voltage; and when the level of the power-on reset signal changes from the high logic level to the low logic level, the output circuit is controlled by the switching signal output to pull down the potential of the output terminal to the zero potential.

In some embodiments, the switching signal output of the audio amplification device of the present disclosure includes: a first switching signal and a second switching signal, and the output circuit includes: a first switch, having a first terminal for receiving a power supply voltage, a second terminal coupled to the gain adjustment circuit to receive the second output signal, and a control terminal for receiving the first switching signal; a second switch, having a first terminal coupled to the second terminal of the first switch, a second terminal coupled to the charge pump circuit to receive the output voltage, and a control terminal for receiving the second switching signal, where when the second switch is turned on, the first switch is turned off; a first output transistor, having a first terminal for receiving a supply voltage, a second terminal coupled to the output terminal of the operational amplifier and outputting the amplified signal, and a control terminal coupled to the gain adjustment circuit to receive the first output signal; and a second output transistor, having a first terminal coupled to the second terminal of the first output transistor, a second terminal coupled to the charge pump circuit to receive the output voltage, and a control terminal coupled to the first terminal of the second switch, where when the level of the power-on reset signal changes from the high logic level to the low logic level, a voltage value of the output voltage is equal to zero, the first switch and the second output transistor are turned on, and the second switch is turned off, so that the potential of the output terminal of the operational amplifier is pulled down to the zero potential.

In some embodiments, in the audio amplification device of the present disclosure, the first switch is a P-type metal-oxide-semiconductor field-effect transistor, and the second switch is an N-type metal-oxide-semiconductor field-effect transistor.

In some embodiments, in the audio amplification device of the present disclosure, the first output transistor is a P-type metal-oxide-semiconductor field-effect transistor, and the second output transistor is an N-type metal-oxide-semiconductor field-effect transistor.

In some embodiments, the charge pump circuit of the audio amplification device of the present disclosure includes: a first transistor, having a first terminal for receiving a supply voltage, a second terminal, and a control terminal for receiving a first control signal; a second transistor, having a first terminal coupled to the second terminal of the first transistor, a grounded second terminal, and a control terminal for receiving a second control signal; a capacitor, having a first terminal coupled to the second terminal of the first transistor, and a second terminal; a third transistor, having a first terminal coupled to the second terminal of the capacitor, a grounded second terminal, and a control terminal for receiving a third control signal; and a fourth transistor, having a first terminal coupled to the second terminal of the capacitor, a second terminal providing the output voltage, and a control terminal for receiving a fourth control signal.

In some embodiments, in the audio amplification device of the present disclosure, the first transistor is a P-type metal-oxide-semiconductor field-effect transistor.

In some embodiments, in the audio amplification device of the present disclosure, the second transistor to the fourth transistor are each an N-type metal-oxide-semiconductor field-effect transistor.

In some embodiments, in the audio amplification device of the present disclosure, the capacitor is a flying capacitor.

In some embodiments, in the audio amplification device of the present disclosure, the power-on reset signal changes with a startup or shutdown of the audio amplification device, and a voltage value of the output voltage is less than or equal to zero.

The present disclosure has the effects that the potential of the output terminal of the operational amplifier is forcibly pulled down to the zero potential by using the change in the output voltage and controlling a turn-on state of the first switch, the second switch and the second output transistor. Thus, the output impedance of the output terminal of the operational amplifier when the audio amplification device shuts down can be greatly reduced, so that the output impedance and the parallel impedance of the load circuit is reduced, thereby improving the problem of shutdown attenuation of the audio amplification device.

### BRIEF DESCRIPTION OF THE DRAWINGS

FIG. 1 is a circuit block diagram illustrating an embodiment of a conventional audio amplification device.

FIG. 2 is a circuit block diagram illustrating an embodiment of an audio amplification device of the present disclosure.

FIG. 3 is a circuit diagram illustrating a charge pump circuit of this embodiment.

FIG. 4 is a circuit diagram illustrating an operational amplifier of this embodiment.

FIG. 5 is a timing chart illustrating waveforms of an enable signal, a power-on reset signal, an output voltage, a switching signal output, a third control signal, and a fourth control signal when the audio amplification device shuts down.

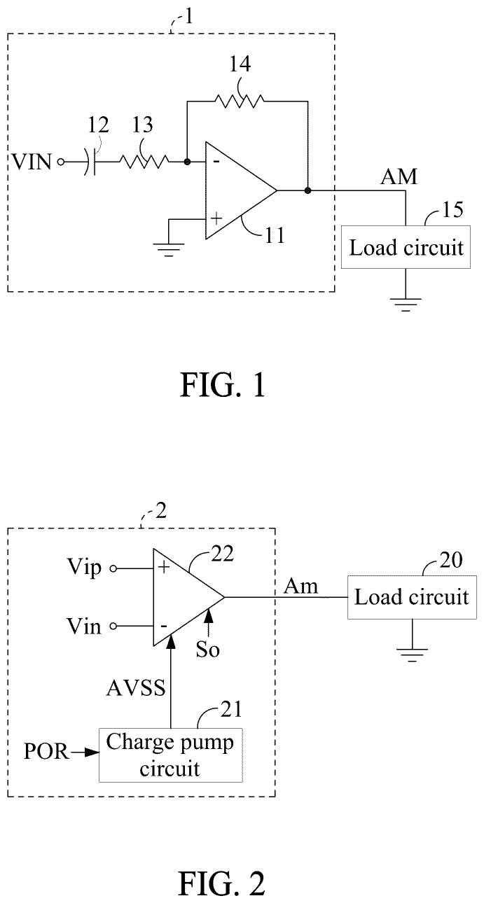

### DETAILED DESCRIPTION OF THE INVENTION

The contents of the present disclosure will be described in detail with the following embodiments and the accompanying drawings, in order to assist those skilled in the art in understanding the purpose, features, and effects of the present disclosure. It should be noted that in the following description and scope of the patent application, the terms “comprising” and “including” are used in an open-ended manner and therefore should not be interpreted as closed terms such as “consisting of”. In addition, the term “coupling” is intended to mean indirect or direct coupling. Therefore, if one apparatus is coupled to another apparatus, this connection can be implemented by either direct coupling, or by indirect coupling via other apparatuses and connections. Moreover, in the following description and scope of the patent application, the terms such as “first”, “second”, and “third” are intended to distinguish differences between elements, and are not intended to limit the elements themselves or to indicate a specific order of the elements.

Referring to FIG. 2, FIG. 2 illustrates an embodiment of an audio amplification device 2 of the present disclosure. The audio amplification device 2 is configured to amplify a low-power audio signal to generate an amplified signal Am and output the amplified signal Am to a load circuit 20. In terms of application, the load circuit 20 may be a loudspeaker, such as a headset or a speaker. The audio amplification device 2 is implemented on a chip. The audio amplification device 2 includes a charge pump circuit 21 and an operational amplifier 22.

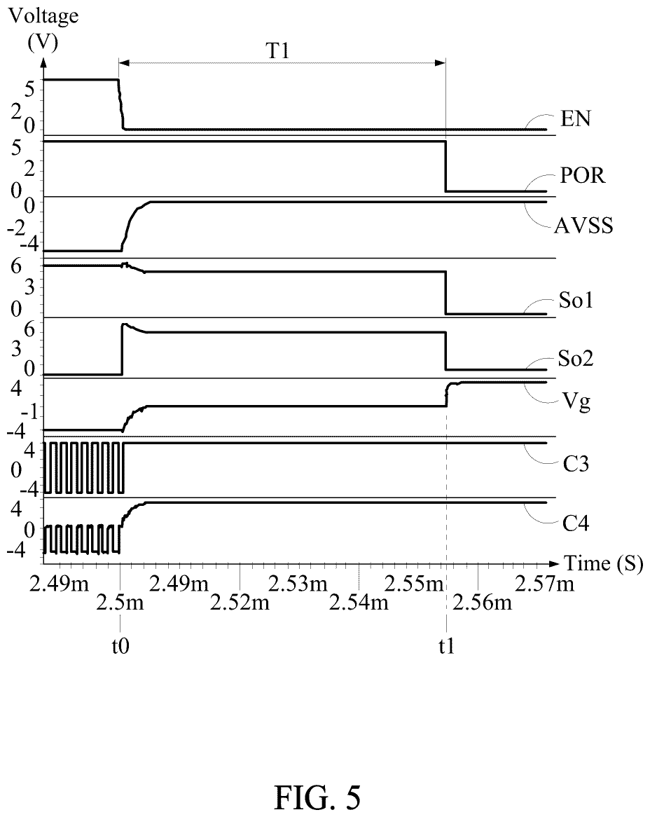

The charge pump circuit 21 is configured to generate an output voltage AVSS when receiving a power-on reset signal POR. The power-on reset signal POR changes with the change in an enable signal (as shown by parameter EN in FIG. 5) for controlling the audio amplification device 2 to start up or shut down. A level of the enable signal is switched between a high logic level and a low logic level. When the level of the enable signal is at the high logic level, the audio amplification device 2 is controlled by the enable signal to start up, and a level of the power-on reset signal POR is the high logic level. At this time, the charge pump circuit 21 is enabled according to the power-on reset signal POR, and a voltage value of the output voltage AVSS generated is less than zero. When the level of the enable signal changes from the high logic level to the low logic level, the audio amplification device 2 is controlled by the enable signal to shut down. At this time, the voltage value of the output voltage AVSS generated by the charge pump circuit 21 gradually changes to zero, and the level of the power-on reset signal POR changes from the high logic level to the low logic level after a preset time (as shown by parameter T1 in FIG. 5).

The operational amplifier 22 has a first input terminal (i.e., a non-inverting input terminal) for receiving a first input signal Vip, a second input terminal (i.e., an inverting input terminal) for receiving a second input signal Vin, a third input terminal coupled to the charge pump circuit 21 to receive the output voltage AVSS, a fourth input terminal for receiving a switching signal output So, and an output terminal. The operational amplifier 22 generates the amplified signal Am at the output terminal according to the first input signal Vip, the second input signal Vin, the output voltage AVSS and the switching signal output So and outputs the amplified signal Am to the load circuit 20. When the level of the power-on reset signal POR changes from the high logic level to the low logic level, the operational amplifier 22 is controlled by the switching signal output So to pull down the potential of the output terminal to zero potential.

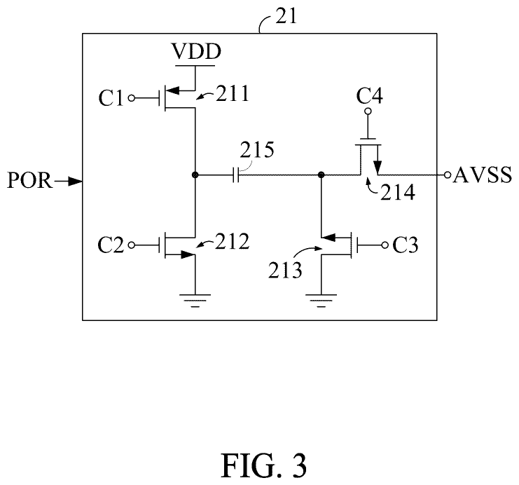

Referring to FIG. 3 further, in this embodiment, the charge pump circuit 21 includes a first transistor 211 to a fourth transistor 214, and a capacitor 215.

The first transistor 211 has a first terminal for receiving a supply voltage VDD, a second terminal, and a control terminal for receiving a first control signal C1. The second transistor 212 has a first terminal coupled to the second terminal of the first transistor 211, a grounded second terminal, and a control terminal for receiving a second control signal C2. The capacitor 215 has a first terminal coupled to the second terminal of the first transistor 211, and a second terminal. The third transistor 213 has a first terminal coupled to the second terminal of the capacitor 215, a grounded second terminal, and a control terminal for receiving a third control signal C3. The fourth transistor 214 has a first terminal coupled to the second terminal of the capacitor 215, a second terminal providing the output voltage AVSS, and a control terminal for receiving a fourth control signal C4. In this embodiment, the first transistor 211 is a P-type metal-oxide-semiconductor field-effect transistor, and the second transistor 212 to the fourth transistor 214 are each an N-type metal-oxide-semiconductor field-effect transistor. The capacitor 215 is a flying capacitor. When the audio amplification device 2 is controlled by the enable signal to start up and the level of the power-on reset signal POR is the high logic level, the charge pump circuit 21 starts to operate normally and is switched back and forth between a first switching state and a second switching state. In the first switching state, the first transistor 211 is controlled by the first control signal C1 to be turned on, the second transistor 212 is controlled by the second control signal C2 to be turned off, the third transistor 213 is controlled by the third control signal C3 to be turned on, and the fourth transistor 214 is controlled by the fourth control signal C4 to be turned off; and in the second switching state, the first transistor 211 is controlled by the first control signal C1 to be turned off, the second transistor 212 is controlled by the second control signal C2 to be turned on, the third transistor 213 is controlled by the third control signal C3 to be turned off, and the fourth transistor 214 is controlled by the fourth control signal C4 to be turned on. Moreover, when the audio amplification device 2 is controlled by the enable signal to shut down and the level of the power-on reset signal POR is the low logic level, the charge pump circuit 21 stops operating, and the first transistor 211 is controlled by the first control signal C1 to be turned off, the second transistor 212 is controlled by the second control signal C2 to be turned on, the third transistor 213 is controlled by the third control signal C3 to be turned on, and the fourth transistor 214 is controlled by the fourth control signal C4 to be turned on.

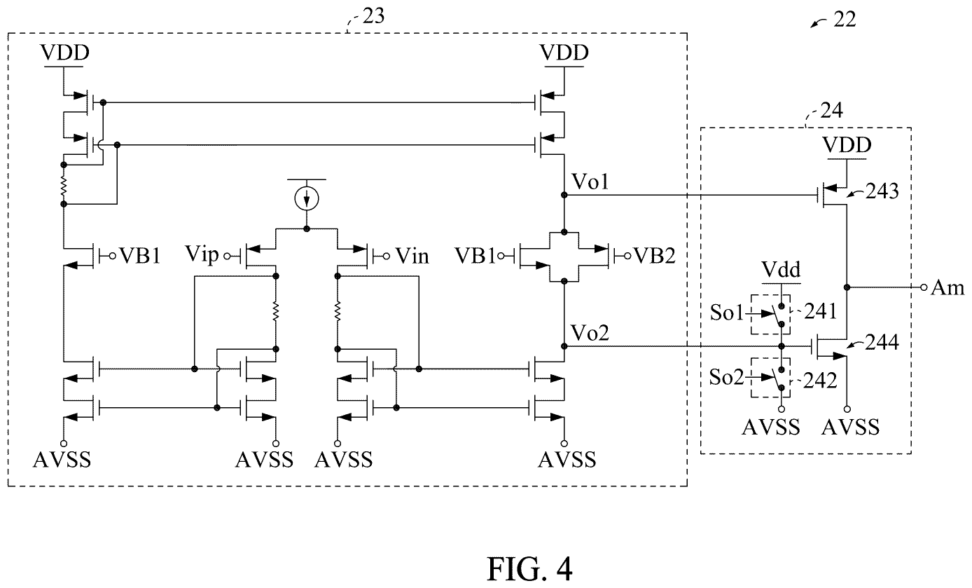

Referring to FIG. 4 further, in this embodiment, the operational amplifier 22 includes a gain adjustment circuit 23 and an output circuit 24. The switching signal output So includes a first switching signal So1 and a second switching signal So2.

The gain adjustment circuit 23 is coupled to the first input terminal to the third input terminal of the operational amplifier 22 to receive the first input signal Vip, the second input signal Vin, and the output voltage AVSS, respectively, and performs gain adjustment according to a voltage bias signal VB1, a voltage bias signal VB2, the first input signal Vip, the second input signal Vin, and the output voltage AVSS to generate a first output signal Vo1 and a second output signal Vo2. It should be noted that the configuration of the gain adjustment circuit 23 is as shown in FIG. 4, and the operation of the gain adjustment circuit 23 is well known to those skilled in the art. For the sake of simplicity, the details will not be repeated here.

The output circuit 24 is configured to receive the first switching signal So1 and the second switching signal So2, and is coupled to the gain adjustment circuit 23 to receive the first output signal Vo1 and the second output signal Vo2, and coupled to the charge pump circuit 21 to receive the output voltage AVSS. The output circuit 24 generates the amplified signal Am at the output terminal of the operational amplifier 22 according to the first switching signal So1 and the second switching signal So2, the first output signal Vo1 and the second output signal Vo2, and the output voltage AVSS. When the level of the power-on reset signal POR changes from the high logic level to the low logic level (i.e., when the audio amplification device 2 shuts down), the output circuit 24 is controlled by the first switching signal So1 and the second switching signal So2 to pull down the potential of the output terminal (i.e., the level of the amplified signal Am) to zero potential, thus reducing output impedance of the output terminal of the operational amplifier 22, and further improving a problem of shutdown attenuation of the audio amplification device 2.

In this embodiment, the output circuit 24 includes a first switch 241, a second switch 242, a first output transistor 243, and a second output transistor 244.

The first switch 241 has a first terminal for receiving a power supply voltage Vdd, a second terminal coupled to the gain adjustment circuit 23 to receive the second output signal Vo2, and a control terminal for receiving the first switching signal So1. The power supply voltage Vdd is a power supply voltage generated inside the operational amplifier 22. The second switch 242 has a first terminal coupled to the second terminal of the first switch 241, a second terminal coupled to the charge pump circuit 21 to receive the output voltage AVSS, and a control terminal for receiving the second switching signal So2. When the second switch 242 is turned on, the first switch 241 is turned off. The first output transistor 243 has a first terminal for receiving the supply voltage VDD, a second terminal coupled to the output terminal of the operational amplifier 22 and outputting the amplified signal Am, and a control terminal coupled to the gain adjustment circuit 23 to receive the first output signal Vo1. The second output transistor 244 has a first terminal coupled to the second terminal of the first output transistor 243, a second terminal coupled to the charge pump circuit 21 to receive the output voltage AVSS, and a control terminal coupled to the first terminal of the second switch 242. In this embodiment, the first switch 241 and the first output transistor 243 are each a P-type metal-oxide-semiconductor field-effect transistor, and the second switch 242 and the second output transistor 244 are each an N-type metal-oxide-semiconductor field-effect transistor.

It should be noted that the first control signal C1 to the fourth control signal C4, and the switching signal output So come from a control circuit (not shown) controlled by a user, and the operation of how the control circuit generates the first control signal C1 to the fourth control signal C4, and the switching signal output So is well known to those skilled in the art. For the sake of simplicity, the details will not be repeated here.

Referring to FIG. 5, FIG. 5 is an operating timing chart of the audio amplification device 2 in this embodiment when shutting down. Parameters EN, POR and AVSS are the above-mentioned enable signal, power-on reset signal, and output voltage, respectively. Parameter T1 is the preset time. Parameters So1 and So2 are the above-mentioned first switching signal and second switching signal, respectively. Parameter Vg is the voltage of the control terminal of the second output transistor 244. Parameters C3 and C4 are the above-mentioned third control signal and fourth control signal, respectively. It should be noted that when the audio amplification device 2 starts up, the first output transistor 243 is controlled by the first output signal Vo1 to be turned off, the first switch 241 is controlled by the first switching signal So1 to be turned off, and the second switch 242 is controlled by the second switching signal So2 to be turned on, so that the voltage of the control terminal of the second output transistor 244 is less than zero, so that the second output transistor 244 is turned off, thus avoiding that the amplified signal Am generated by the operational amplifier 22 is influenced by the potential of the second terminal of the second output transistor 244, and other circuit operations in the operational amplifier 22 are the same as operating programs of normal startup of the conventional operational amplifiers. After the startup timing, the first output transistor 243 and the second output transistor 244 are controlled by the first output signal Vo1 and the second output signal Vo2, respectively, to be turned on or turned off so as to generate the amplified signal Am, which is well known to those skilled in the art. For the sake of simplicity, the details will not be repeated here.

When the level of the enable signal EN changes from the high logic level to the low logic level (i.e., at time point t0), the audio amplification device 2 is controlled by the enable signal EN to shut down, the first transistor 211 is controlled by the first control signal C1 to be turned off, and the second transistor 212 is controlled by the second control signal C2 to be turned off, and the third transistor 213 and the fourth transistor 214 are controlled by the third control signal C3 and the fourth control signal C4, respectively, to be turned on, so that the voltage value of the output voltage AVSS generated by the charge pump circuit 21 gradually changes from less than zero to equal to zero. At this time, the first output transistor 243 is controlled by the first output signal Vo1 to be turned off, the first switch 241 is controlled by the first switching signal So1 to be turned off continuously, and the second switch 242 is controlled by the second switching signal So2 to be turned on continuously, so that the voltage Vg of the control terminal of the second output transistor 244 is less than its turn-on voltage continuously, so that the second output transistor 244 is turned off, thus avoiding that the potential of the output terminal of the operational amplifier 22 is influenced by the potential of the second terminal of the second output transistor 244, i.e., avoiding that the amplified signal Am changes with the change in the output voltage AVSS, which thus can avoid that the load circuit 20 additionally generates discontinuous pop noise similar to bo bo.

When the level of the enable signal EN changes from the high logic level to the low logic level and after the preset time T1 (i.e., at time point t1), the first transistor 211 is controlled by the first control signal C1 to be turned off continuously, and the second transistor 212 is controlled by the second control signal C2 to be turned off continuously, and the third transistor 213 and the fourth transistor 214 are controlled by the third control signal C3 and the fourth control signal C4, respectively, to be turned on continuously, so that the voltage value of the output voltage AVSS generated by the charge pump circuit 21 is fixed at equal to zero. At this time, the first output transistor 243 is controlled by the first output signal Vo1 to be turned off, the first switch 241 is controlled by the first switching signal So1 to be switched from turn off to turn on, and the second switch 242 is controlled by the second switching signal So2 to be switched from turn on to turn off, so that the voltage Vg of the control terminal of the second output transistor 244 changes to greater than its turn-on voltage, so that the second output transistor 244 is switched from turn off to turn on to forcibly pull down the level of the amplified signal Am to the zero potential, which thus can greatly reduce the output impedance of the output terminal of the operational amplifier 22, thereby improving the problem of shutdown attenuation of the audio amplification device 2. It should be added that the preset time T1 is used for ensuring that the voltage value of the output voltage AVSS really changes to equal to zero.

To sum up, in the present disclosure, when the audio amplification device 2 shuts down, the level of the amplified signal Am is forcibly pulled down to the zero potential by the change in the output voltage AVSS and by controlling a turn-on state of the first switch 241, the second switch 242 and the second output transistor 244. Thus, the audio amplification device 2 will not generate additional current consumption when shutting down, and the output impedance of the output terminal of the operational amplifier 22 can be greatly reduced, so that the output impedance and the parallel impedance of the load circuit 20 is reduced, thereby improving the problem of shutdown attenuation of the audio amplification device 2. Moreover, the charge pump circuit 21 used in the present disclosure is an in-chip conventional circuit for implementing the audio amplification device 2, and is not an additional transistor/circuit element. Thus, the overall circuit configuration of the present disclosure for improving the problem of shutdown attenuation of the audio amplification device 2 will not have a relatively large circuit area.

The above is only an embodiment of the present disclosure, and the scope of the embodiment of the present disclosure cannot be limited by this, and all simple equivalent changes and modifications made in accordance with the scope of the patent application for the present disclosure and the contents of the patent description still fall within the scope of the patent of the present disclosure.

While the present invention has been described by means of specific embodiments, numerous modifications and variations could be made thereto by those skilled in the art without departing from the scope and spirit of the present invention set forth in the claims.

What is claimed is:

1. An audio amplification device, comprising:
a charge pump circuit, configured to generate an output voltage when receiving a power-on reset signal; and
an operational amplifier, having a first input terminal for receiving a first input signal, a second input terminal for receiving a second input signal, a third input terminal coupled to the charge pump circuit to receive the output voltage, a fourth input terminal for receiving a switching signal output, and an output terminal, wherein the operational amplifier generates an amplified signal at the output terminal according to the first input signal, the second input signal, the output voltage, and the switching signal output, and outputs the amplified signal to a load circuit; and when a level of the power-on reset signal changes from a high logic level to a low logic level, the operational amplifier is controlled by the switching signal output to pull down a potential of the output terminal to zero potential.

2. The audio amplification device according to claim 1, wherein the operational amplifier comprises:
a gain adjustment circuit, coupled to the first input terminal to the third input terminal of the operational amplifier to receive the first input signal, the second input signal, and the output voltage, respectively, and performing gain adjustment according to the first input signal, the second input signal, and the output voltage to generate a first output signal and a second output signal; and
an output circuit, configured to receive the switching signal output, and coupled to the gain adjustment circuit to receive the first output signal and the second output signal, and coupled to the charge pump circuit to receive the output voltage, wherein the output circuit generates the amplified signal at the output terminal of the operational amplifier according to the switching signal output, the first output signal, the second output signal, and the output voltage; and when the level of the power-on reset signal changes from the high logic level to the low logic level, the output circuit is controlled by the switching signal output to pull down the potential of the output terminal to the zero potential.

3. The audio amplification device according to claim 2, wherein the switching signal output comprises a first switching signal and a second switching signal, and the output circuit comprises:
a first switch, having a first terminal for receiving a power supply voltage, a second terminal coupled to the gain adjustment circuit to receive the second output signal, and a control terminal for receiving the first switching signal;
a second switch, having a first terminal coupled to the second terminal of the first switch, a second terminal coupled to the charge pump circuit to receive the output voltage, and a control terminal for receiving the second switching signal, wherein when the second switch is turned on, the first switch is turned off;
a first output transistor, having a first terminal for receiving a supply voltage, a second terminal coupled to the output terminal of the operational amplifier and outputting the amplified signal, and a control terminal coupled to the gain adjustment circuit to receive the first output signal; and
a second output transistor, having a first terminal coupled to the second terminal of the first output transistor, a second terminal coupled to the charge pump circuit to receive the output voltage, and a control terminal coupled to the first terminal of the second switch,
wherein when the level of the power-on reset signal changes from the high logic level to the low logic level, a voltage value of the output voltage is equal to zero, the first switch and the second output transistor are turned on, and the second switch is turned off, so that the potential of the output terminal of the operational amplifier is pulled down to the zero potential.

4. The audio amplification device according to claim 3, wherein the first switch is a P-type metal-oxide-semiconductor field-effect transistor, and the second switch is an N-type metal-oxide-semiconductor field-effect transistor.

5. The audio amplification device according to claim 3, wherein the first output transistor is a P-type metal-oxide-semiconductor field-effect transistor, and the second output transistor is an N-type metal-oxide-semiconductor field-effect transistor.

6. The audio amplification device according to claim 1, wherein the charge pump circuit comprises:
a first transistor, having a first terminal for receiving a supply voltage, a second terminal, and a control terminal for receiving a first control signal;
a second transistor, having a first terminal coupled to the second terminal of the first transistor, a grounded second terminal, and a control terminal for receiving a second control signal;
a capacitor, having a first terminal coupled to the second terminal of the first transistor, and a second terminal;
a third transistor, having a first terminal coupled to the second terminal of the capacitor, a grounded second terminal, and a control terminal for receiving a third control signal; and
a fourth transistor, having a first terminal coupled to the second terminal of the capacitor, a second terminal providing the output voltage, and a control terminal for receiving a fourth control signal.

7. The audio amplification device according to claim 6, wherein the first transistor is a P-type metal-oxide-semiconductor field-effect transistor.

8. The audio amplification device according to claim 6, wherein the second transistor to the fourth transistor are each an N-type metal-oxide-semiconductor field-effect transistor.

9. The audio amplification device according to claim 6, wherein the capacitor is a flying capacitor.

10. The audio amplification device according to claim 1, wherein the power-on reset signal changes with a startup or shutdown of the audio amplification device, and a voltage value of the output voltage is less than or equal to zero.
